(19) United States
(12) Patent Application Publication
(10) Pub. No.: US 2025/0031409 A1
(43) Pub. Date: Jan. 23, 2025

(54) SEMICONDUCTOR COMPONENT AND METHOD FOR PRODUCING A SEMICONDUCTOR COMPONENT

(71) Applicant: Robert Bosch GmbH, Stuttgart (DE)

(72) Inventors: Alberto Martinez-Limia, Pliezhausen (DE); Holger Bartolf, Ofterdingen (DE); Jan-Hendrik Alsmeier, Pfullingen (DE); Stephan Schwaiger, Bodelshausen (DE); Dragos Costachescu, Reutlingen (DE); Wolfgang Feiler, Reutlingen (DE)

(21) Appl. No.: 18/439,895

(22) Filed: Feb. 13, 2024

(30) Foreign Application Priority Data
Feb. 22, 2023 (DE) 10 2023 201 561.7

(51) Int. Cl. H01L 29/78; H01L 29/06; H01L 29/423; H01L 29/66

(52) U.S. Cl. CPC H01L 29/7813; H01L 29/0603; H01L 29/4236; H01L 29/66734

(57) ABSTRACT

A semiconductor component, in particular a transistor. The semiconductor component includes: source and drain layers doped according to a first type, a channel layer located vertically between the source layer doped and the drain layer, and a gate trench, which extends vertically from the source layer to the drain layer and adjoins the channel layer and at least a portion of the source layer. A first shielding region doped according to a second type, extends vertically from the source layer, or a semiconductor surface adjoining it, to the drain layer, and a second shielding region doped according to the second type, is arranged vertically below a bottom of the gate trench, wherein the gate trench and the second shielding region are designed such that, in one or more delimited regions, the second shielding region extends horizontally at least to the first shielding region.

### CROSS REFERENCE

The present application claims the benefit under 35 U.S.C. § 119 of German Patent Application No. DE 10 2023 201 561.7 filed on Feb. 22, 2023, which is expressly incorporated herein by reference in its entirety.

### FIELD

The present invention relates to a semiconductor component, in particular a transistor, e.g., a so-called trench MOSFET, and to a method for producing such a semiconductor component.

### BACKGROUND INFORMATION

Semiconductor components such as field-effect transistors (FETs), in particular so-called MOSFETs, are used in various fields. A variant of this are so-called trench MOSFETs or T-MOSFETs, in which one channel is vertical. In this case, for example, an n-doped source layer and a channel layer located between this source layer and one of the n-doped drift layers are interrupted by trenches; gate electrodes are then arranged in such trenches.

### SUMMARY

According to the present invention, a semiconductor component and a method for producing a semiconductor component are provided. Advantageous example embodiments of the present invention are disclosed herein.

The present invention relates to semiconductor components and their production. In particular transistors, preferably field-effect transistors, viz., in particular with trenches, come into consideration as semiconductor components. They can then, for example, be T-MOSFETs or T-MISFETs. Different types of doping, specifically n-doping and p-doping, are used with semiconductor materials, wherein different components can be doped differently. For the sake of clarity, semiconductor components are to be described below with a specific type of doping; n-doping is to be a doping of a first type, p-doping is to be a doping of a second type. However, it is understood that n-doping and p-doping can also be interchanged; i.e., the n-doping could be the second type of doping and the p-doping could be the first type of doping.

Although the present invention is described primarily with respect to a field-effect transistor, it can also be applied to other transistors, e.g., IGBTs, and, in general, semiconductor elements, such as diodes, provided that the transistor or the semiconductor component has a corresponding structure with a gate trench.

According to an example embodiment of the present invention, a field-effect transistor, for example, has an n-doped source layer and an n-doped drain layer (in particular comprising an n-doped drift layer, for example applied as a so-called epitaxy layer or epitaxial layer). In addition, it has a channel layer located vertically between the n-doped source layer and the n-doped drift layer. The channel layer can be at least partially p-doped. Typically, the n-doped drain layer comprises an n-doped drift layer and an n-doped spread layer which has a higher n-doping than the n-doped drift layer. In this case, the n-doped spread layer is provided vertically between the channel layer and the n-doped drift layer, i.e., the n-doped spread layer adjoins the channel layer. This n-doped spread layer can, for example, be obtained by suitable doping of a portion of the n-doped drain layer. Furthermore, such a field-effect transistor typically has a gate trench which extends vertically from the n-doped source layer to the n-doped drift layer and adjoins the channel layer and at least a portion of the source layer, thus in particular also passes through the channel layer.

Furthermore, according to an example embodiment of the present invention, the field-effect transistor can comprise an insulated gate electrode which the conductive gate electrode material of which is at least partially surrounded by a dielectric (e.g., so-called gate oxide), viz., in particular, in such a way that the gate electrode or the conductive gate electrode material is thereby insulated from the n-doped source layer, the channel layer, and the n-doped drain layer. A field-effect transistor may also have a plurality of these gate trenches, wherein such a gate electrode can then be arranged at each gate trench.

Furthermore, according to an example embodiment of the present invention, such a field-effect transistor can have at least one p-doped first shielding region which extends vertically from the n-doped source layer, or a semiconductor surface adjoining (adjacent to) said layer (the n-doped source layer), to the n-doped drain layer.

It is understood that, in addition to the gate electrodes, such a field-effect transistor also has source and drain connections, which can be formed in a conventional manner.

A particular advantage of a trench MOSFET is, for example, that the vertical arrangement makes it possible to arrange many gate electrodes next to one another. The field-effect transistor can in particular be formed as a SiC or GaN field-effect transistor, i.e., a substrate and/or commonly used semiconductor material can be silicon carbide (SiC) or gallium nitride (GaN) since these semiconductor materials have a wide band gap. However, semiconductor materials having an ultra-wide band gap, for example gallium oxide, can also be considered. However, the present invention can in general also be used with other semiconductor materials, such as gallium nitride (GaN), silicon (Si) or germanium (Ge).

A challenge with such field-effect transistors, e.g., silicon carbide (SiC) trench-gate-power MISFETs, is to achieve good forward properties (i.e., a low area-specific resistance) with good resistance to short-circuiting and to also limit the maximum field strength in the insulator of the trench to acceptable values, e.g., in the order of magnitude of 3 MV/cm, at a high blocking voltage for reasons of reliability.

One possibility for achieving a good resistance to short-circuiting is to limit the current density in the event of a short circuit to the smallest possible values since the power loss density and the heating rate of the field-effect transistor or of a component in which the field-effect transistor is contained is thus limited and timely switching-off of the component before it is damaged or destroyed can be made possible.

Furthermore, according to an example embodiment of the present invention, such a field-effect transistor can have a p-doped (or, in general, doped according to the second type) second shielding region which is arranged vertically below a bottom of the gate trench. This can also be referred to as a so-called buried, p-doped structure (bottom p-well, BPW). Said structure can be arranged directly below the bottom of the gate trench (trench bottom). In particular, said structure can extend horizontally like the gate trench, especially since this p-doped second shielding region can be obtained, for example, by implantation into the gate trench.

Like the gate trench, this p-doped second shielding region or this p-doped structure can, for example, be grid-shaped and connected to source or a source potential via special contact cells. One contact cell can in this case be used for a plurality of active field-effect transistor cells, e.g., in a ratio of 9:1, in order not to obtain an excessively large increase in the specific switch-on resistance, since these contact cells do not contribute to the operation of the transistor. The p-doped structure held at source potential serves to reduce the field strength in the insulator of the gate trench (i.e., of the gate dielectric that surrounds the gate electrode) and to increase the resistance to short-circuiting. The contacting of the p-doped structure in the contact cell can take place, for example, by means of a trench which is filled with source metal and extends vertically to the p-doped structure.

However, as has been shown, the use of individual cells has the disadvantage that, in the event of faults of the contacting, for example as a result of particles during manufacturing, some individual cells are not contacted or are not sufficiently contacted. Therefore, a strip-shaped cell design is to be preferred which, below the gate trench, contains a p-doped structure (p-doped second shielding region) arranged at or without a vertical distance therefrom, for protecting the gate insulator (or gate dielectric) against high fields in the blocking case and for optimizing the short-circuit behavior of the field-effect transistor.

According to an example embodiment of the present invention, for the p-doped structure (p-doped second shielding region) arranged vertically below the gate trench, it is desirable to achieve a contacting with the source potential, while, however, additional channel zones should be provided as much as possible in order to keep the switch-on resistance in the forward case low.

A possible contacting concept for this purpose is that the p-doped first shielding region is brought to the gate trench and thus to the p-doped second shielding region arranged therebelow, so that the p-doped first shielding region touches or partially encloses or overlaps with this p-doped second shielding region. However, no channel can then be formed in this region, which is, however, disadvantageous for the switch-on resistance.

Another possible contacting concept for this purpose is that buried layers are used, the production of which is, however, complicated since the growth of the drift zone (in the n-doped source layer) on the substrate has to be interrupted in order to implant the buried layer, and the growth of the drift zone has to subsequently be continued.

A further possible contacting concept for this purpose is that a strip-shaped cell is interrupted in the strip direction in order to achieve the contacting of the p-doped second shielding region by deep, more highly p-doped regions which are implanted from the surface of the component with high energy and extend to the p-doped second shielding region. However, as a result of this interruption of the strip cell, no channel can be formed in this region, which is disadvantageous for the switch-on resistance.

In the context of the present invention, a more advantageous contacting concept is now provided. The gate trench and the second shielding region doped according to the second type (e.g., p− or p+) are or will in this case be designed in such a way that, in one or more delimited regions, the second shielding region doped according to the second type (e.g., p− or p+) is or will be brought horizontally at least to the first shielding region doped according to the second type (e.g., p− or p+).

According to an example embodiment of the present invention, the p-doped first shielding region is thus not brought to the gate trench with a p-doped second shielding region arranged therebelow, but rather the gate trench with a p-doped second shielding region arranged therebelow is brought to the p-doped first shielding region. If the gate trench is substantially strip-shaped in a preferred direction, substantially web-shaped guide regions starting therefrom, e.g., in the direction pointing away laterally therefrom, with a p-doped second shielding region arranged therebelow exist and extend to or into the p-doped first shielding region. The gate trench and the second shielding region doped according to the second type (p− or p+) can, as seen in the horizontal direction, thus be strip-shaped with one or more branching-off webs which extend to the one or more delimited regions.

This geometric design makes it possible to form additional channel regions which at least partially compensate for the disadvantageous effect that no channel can be formed in the contact region of the gate trench with the p-doped first shielding region. This is in particular due to the fact that the formation of the gate trench and thus also of the p-doped second shielding region located therebelow makes the formation of channel zones in the region of the branching-off webs possible.

In one embodiment of the present invention, the gate trench can be formed first, possibly with the webs, and only thereafter the p-doped second shielding region. This can then take place, for example, by means of implantation into the gate trench, in particular a bottom of the gate trench.

Such a field-effect transistor can be used alone or together with others, for example as a power switch. Preferred fields of application are, for example, in an electric drive train of a vehicle, for example in a current transformer (DC/DC converter, inverter), in charging devices for electrically powered vehicles or in solar inverters.

Further advantages and embodiments of the present invention can be found in the disclosure herein.

The present invention is shown schematically in the figures on the basis of exemplary embodiments and is described below with reference to the figures.

### BRIEF DESCRIPTION OF THE DRAWINGS

FIG. 1 schematically shows a semiconductor component according to the present invention in a preferred embodiment.

FIG. 2 schematically shows a semiconductor component according to the present invention in a further preferred embodiment.

FIG. 3 schematically shows a sequence of a method according to the present invention in a preferred embodiment.

### DETAILED DESCRIPTION OF EXAMPLE EMBODIMENTS

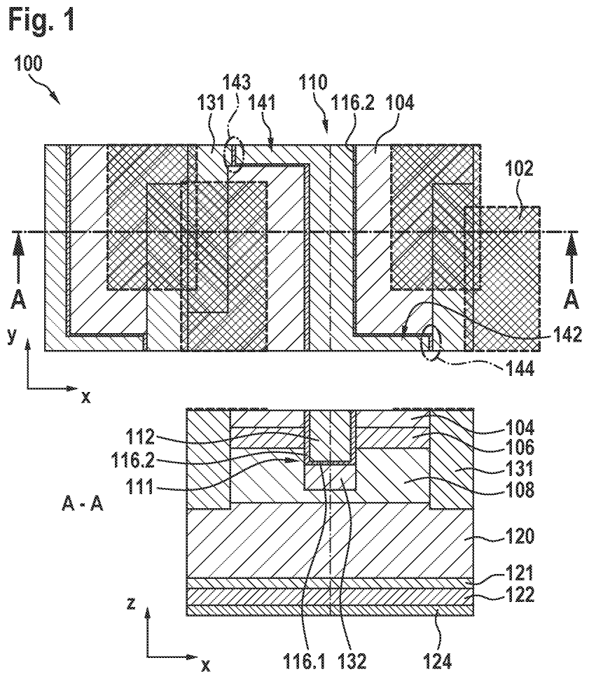

FIG. 1 schematically shows a semiconductor component 100 according to the present invention (or at least an active portion thereof) in a preferred embodiment, viz., as a field-effect transistor, in particular a so-called trench MISFET. Silicon carbide (SiC), gallium nitride (GaN) or gallium oxide can in particular be used as the semiconductor material since these semiconductor materials have a wide to very wide band gap. FIG. 1 shows a plan view at the top, and an associated sectional view along the line A-A through the field-effect transistor 100 at the bottom. Both views are to be described comprehensively below.

The field-effect transistor 100 has an n-doped (in particular n+-doped) source layer 104, an n-doped drain layer and a channel layer 106 located vertically (here corresponding to the z-direction) between the n-doped source layer 104 and the n-doped drain layer. The channel layer 106 (or also body zone) can be completely or partially p-doped.

The n-doped drain layer can, for example, comprise an n-doped drift layer 120 and can comprise an n-doped spread layer 108, wherein the n-doped spread layer 108 adjoins the channel layer 106, i.e., is located at the top. The n-doped drain layer can, for example, also comprise an n-doped buffer layer 121, which is in particular located at the bottom, as seen in the vertical direction.

The field-effect transistor 100 furthermore has one or more p-doped (in particular p+-doped) first shielding regions 131 which extend vertically from the n-doped source layer 104 or the neighboring semiconductor surface to the n-doped drain layer. In FIG. 1, the first shielding regions 131 are substantially strip-shaped and can be partially overdoped in their upper region by the n-doped source layer 104 in order to ensure reliable contacting of the first shielding regions 131 and n-doped source layer 104 by the source material 102 even if adjustment tolerances of the individual zones relative to one another occur. The channel layer 106 is in contact with the at least one first shielding zone 131.

The buffer layer 121, which is typically very highly doped in comparison to the n-doped drift layer 120, is optional and can serve to minimize the switch-on resistance by a punch-through design and to achieve the robustness of the field-effect transistor with respect to bipolar degradation. The n-doped spread layer 108 is also optional. In order to achieve a low switch-on resistance, said spread layer is typically more highly doped than the drift layer 120 and can extend vertically from the channel layer 106 to below the p-doped first shielding regions 131.

Furthermore, the field-effect transistor 100 has an n-doped (in particular n+-doped) substrate 122 which adjoins the n-doped drain layer at the bottom, and there in particular the n-doped buffer layer 121, as well as a drain material 124, e.g., a metal, which adjoins the n-doped substrate 122 at the bottom. Furthermore, the field-effect transistor 100 has a source material 102, e.g., a metal, which adjoins the n-doped source layer 104 and the at least one first shielding zone 131 at the top, wherein here, in particular, only regions in which the source material comes into contact are indicated.

The field-effect transistor 100 has one or more gate electrodes 110 together with insulation, which are each introduced into one of a plurality of gate trenches 111. The gate trenches extend vertically (here in the z-direction) from the n-doped source layer 104 to the n-doped drain layer, here into the n-doped spread layer 108, and adjoin the channel layer 106 and at least partially the source layer 104.

The gate electrodes 110 with insulation in each case have, for insulation, a dielectric or gate oxide 116.1, 116.2, which at least partially surrounds a conductive gate electrode material, preferably a semiconductor material, 112. Via the dielectric 116.2, the gate electrode with the insulation (and thus also the associated gate trench) laterally adjoins at least the channel layer 106 and at least partially the source layer 104, and, via the dielectric 116.1, adjoins a bottom of the gate trench.

The gate trench 111 can thus be lined with the dielectric 116.1, 116.2 of a defined thickness. The dielectric 116.1 at the bottom of the gate trench (trench bottom) can have a different, e.g., greater, thickness than the dielectric 116.2 on the side walls. The dielectric (or insulator) can, for example, be a homogeneous insulator, or else an inhomogeneous insulator, e.g., an insulator stack constructed from layers; in general, materials such as SiO2, high-k materials, SiN, Al2O3, HfO can be used, for example. Furthermore, the dielectric 116.1 at the bottom of the gate trench can consist of a different material than the dielectric 116.2 on the side walls and/or can have a different ratio of the insulator stack materials in the case of an insulator stack.

The gate electrodes are used to control a channel zone in the channel layer 106. In this case, a region in the channel layer 106 which adjoins the gate electrode or the gate trench forms the channel zone or a channel region. The gate electrodes 110 or the actual conductive electrode material 112 of the gate is located within the gate trench 111 and adjoins the dielectric 116.1, 116.2. It may also be separated from the source metalization (source material 102) by a further insulator (not shown).

A trench MISFET substantially has the active zone, which generally consists of a multitude of the parallel connected cells shown in FIG. 1, and connection regions (not shown here) for the gate, and also source metal and edge termination zones. The connection regions for the gate (gate introduction, i.e., the contacting of the gate electrodes 110) takes place, for example, at the end of a cell field in the y-direction, in that the material 112 leaves the trench there.

Adjoining or even interpenetrating zones or regions of the same doping type, i.e., for example, n- or p-doped, are in particular conductively connected to one another. In particular, contacts between metal and semiconductor are also to be understood as low-resistance ohmic contacts, such as between the source metal 102 and source layer 10 as well as the p-doped first shielding regions 131 or drain metal 124 and substrate 122.

Starting from doping concentrations n and p without additional signs, n− and p− (with minus sign) are intended to denote significantly lower, and n+ and p+ (with plus signs) are intended to denote significantly higher doping concentrations of preferably at least a factor of 10 relative to the concentrations without additional signs. The source potential is intended to serve as a reference potential in the following explanation of the mode of operation.

The active zone of the field-effect transistor 100 can comprise substantially strip-shaped cells which are, preferably periodically, continued laterally perpendicularly (e.g., in the x-direction) to the MIS cell alignment (e.g., in the y-direction) in order to minimize inhomogeneities in the component.

The field-effect transistor 100 furthermore has p-doped (in particular p+-doped) second shielding regions 132 which are arranged vertically (here in the z-direction) below a bottom of the gate trench 111. A p-doped second shielding region 132 can but does not have to vertically adjoin the bottom of the gate trench (trench bottom).

In principle, the p-doped second shielding region 132 shields the gate insulator or the dielectric 116.1, 116.2, in particular in the region of the trench bottom (i.e., dielectric 116.1), from high fields which occur in the case of high drain-source voltages. As a result, the p-doped first shielding regions 131 can be designed to be flatter (in the z-direction), which is less complex and, on the one hand, reduces crystal damage due to the implantation used, for example, for the production thereof. On the other hand, flatter p-doped first shielding regions 131 allow a smaller cell pitch since the implantation mask can be designed to be less thick and thus more finely structured.

In addition, flatter p-doped first shielding regions 131 lead to a better current distribution in the lateral direction and thus to a lower switch-on resistance, and the dynamic behavior of the intrinsic body diode of the field-effect transistor, e.g., in reverse recovery, is also improved by a lower charge carrier flooding of the drift zone in diode forward operation, as is the robustness with respect to bipolar degradation.

The p-doped first shielding regions 131 do not have to be deeper (i.e., extend further downward in the z-direction) than the p-doped second shielding regions 132 and/or the spread layer 108. The spread layer 108 does not necessarily have to be deeper than the p-doped first shielding region 131.

The gate trench 111 and the p-doped second shielding region 132 are now designed in such a way that, in one or more delimited regions, the p-doped second shielding region 132 extends horizontally (as seen in a plane parallel to the x-y plane) at least to the p-doped first shielding region 131. For this purpose, the gate trench 111 and the p-doped second shielding region 132 are in particular strip-shaped as seen in the horizontal direction (here, for example, a strip in the y-direction) with one or more branching-off webs, in particular in the lateral direction to the strip (here in the x-direction), which extend to the one or more delimited regions. This can apply correspondingly to further gate trenches and associated p-doped second shielding regions as well as further p-doped first shielding regions. The term “delimited region” is here understood in particular to mean that a p-doped second shielding region is brought to and contacts a p-doped first shielding region only at certain locations, but not everywhere, so that a channel can continue to be formed at other locations.

In the example in FIG. 1, the gate trench 111 and the p-doped second shielding region 132 have two webs 141, 142 which branch off the otherwise strip-shaped gate trench 111 on different sides. These webs 141, 142 each extend to a p-doped first shielding region 131, to the delimited regions 143, 144 indicated by means of a circle in each case. In particular, the p-doped first shielding region and the p-doped second shielding region can then, for example, also overlap, i.e., establish an electrical contact. In FIG. 1, this is not directly visible, but a p-doped second shielding region is present everywhere below the bottom of the gate trench 111, i.e., also in the webs 141, 142 and thus in the delimited regions 143, 144.

As shown, the webs can alternately laterally branch off the (actual) gate trench but can also be substantially opposite one another (which would be seen here, for example, at the same height in the y-direction). A distance between a web and delimited region (along the extension direction of the gate trench, here the y-direction) to the next web or delimited region on the same side of the gate trench can be selected freely. A favorable compromise between low resistance of the connection of the p-doped second region 132 to the source potential is, for example, approximately between twice to twenty times the cell pitch of the strip cell of the field-effect transistor.

In the forward case, the source material 102 and the p-doped second shielding region 132 are at the source potential, which here functions as the reference potential, the conductive gate electrode material 112 of the gate electrode 110 is at a positive gate potential relative to the reference potential, and the drain material 124 is at a small positive drain potential of, for example, a few volts relative to the reference potential. If the gate potential at the gate electrode 110 is below the so-called threshold voltage, only a small blocking current flows from the drain material 124 to the source material 102 (i.e., from the drain to the source). If the gate voltage at the gate electrode 110 is increased to above the threshold voltage, so many electrons are attracted as a result of the influence effect to the gate-insulator-side surface of the regions of the channel layer 106 that laterally adjoin the gate trench 111 that a conductive channel forms there. A low-resistance current path from the drain material 124, through the substrate 122, the optional buffer layer zone 121, the drift layer 120, the spread layer 108, the channels formed at the gate-insulator-side surfaces in the channel layer 106, the source layer 104 to the source material 102 is thus opened and the component is able to conduct a high current density.

In the regions in which a p-doped first shielding region 131 adjoins the gate trench 111, no considerable formation of a channel is possible due to the locally very high threshold voltage there. On the other hand, the gate trench 111 is brought to the p-doped first shielding region 131 by the webs 141, 142 branching laterally off the otherwise strip-shaped gate trench 111. Due to this geometric design, the formation of additional channel regions in the channel layer 106 at the side walls adjoining the webs is possible, which additional channel regions at least partially compensate for the disadvantageous effect that no channel can be formed in the contact region of the gate trench 111 with the p-doped first shielding region 131.

Although the space charge zones formed between the p− or p+-doped first and second shielding regions 131, 132 and the adjoining n-doped regions or layers are narrow, they have a current constricting effect, which is initially unfavorable for a small specific switch-on resistance. However, these locally higher voltage drops can be at least partially counteracted by a corresponding n-doping of the spread layer 108 by these dopings being higher than the doping of the drift layer 120. Depending on the required blocking ability, however, the doping of the spread layer 108 can also be as high as the doping of the drift layer 120 and the vertical extension can be adapted to the spread layer 108.

In the case that the spread layer 108 is more highly doped than the drift layer 120, the following applies: the blocking ability of the component decreases the greater the vertical extension of the spread layer 108 is.

In the blocking case, the gate voltage is below the threshold voltage and the drain voltage is a positive voltage relative to the reference potential. With increasing drain voltage, the space charge zones of the pn transitions receiving the blocking voltage between the p− or p+-doped first and second shielding regions 131, 132 as well as the channel layer 106 and the adjoining, respectively lower n-doped spread and drift layers 108, 120 expand substantially into the n-doped zones; with increasing blocking voltage also further into the drift layer 120, while the p-doped first and second shielding regions 131, 132 and the channel layer 106 are not completely removed. In particular, a non-removed path remains between the p-doped first and second shielding regions 131, 132 so that the p-doped second shielding region 132 remains connected to the source potential.

This is achieved in that the lateral webs 141, 142 of the gate trench 111 extend to or even into the p+ zones. In particular, the space charge zones starting from the p-doped first and second shielding regions 131, 132 grow laterally toward one another and finally together so that, from a so-called pinch-off voltage that is small relative to the intermediate circuit voltage, the channel layer 106 or the regions for the channels there are shielded as far as possible from further field increases with further increasing blocking voltage. In this case, the p-doped second shielding region 132 in particular shields the bottom of the gate trench 111 and the corners and/or roundings thereof, wherein the shielding effect becomes greater, the smaller the vertical distance of the p-doped second shielding region 132 from the bottom of the gate trench 111 is.

In the short-circuit case, if a high voltage relative to the reference potential is applied at the drain material 124 or at the drain and a voltage above the threshold voltage is applied at the gate or at the gate electrode 110, a comparatively high current flows through the component. As a result of the shielding effect of the p-doped first and second shielding regions 131, 132, which is described above for the blocking case, with respect to the passage of high fields onto the channel layer 106 and the bottom of the gate trench 111, a smaller short-circuit current and thus a higher resistance to short-circuiting is achieved than would be the case without a p-doped second shielding region 132 at the source potential.

The contacting concept described is not limited to strip-shaped cells; rather, the underlying idea can be transferred to various geometric embodiments.

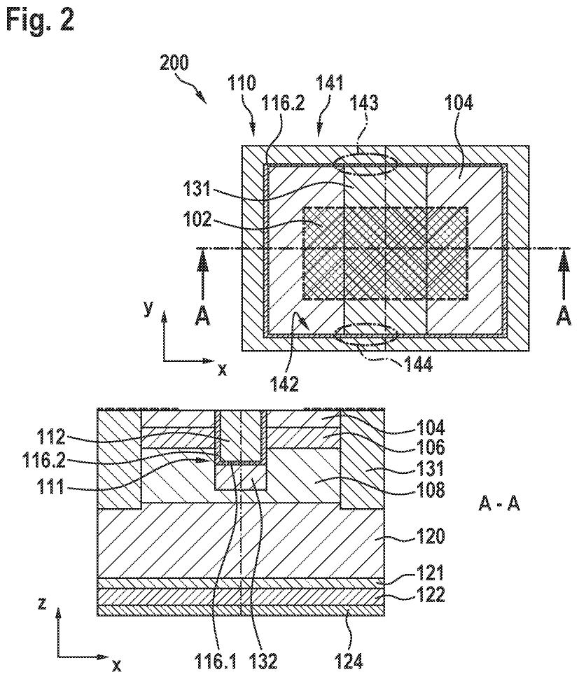

FIG. 2 schematically shows a semiconductor component 200 according to the present invention (or at least an active portion thereof) in a further preferred embodiment, viz., as a field-effect transistor, in particular a so-called trench MISFET. FIG. 2 shows a plan view at the top, and an associated sectional view along the line A-A through the field-effect transistor 200 at the bottom. Both views are to be described comprehensively below. In terms of the basic mode of operation, the field-effect transistor 200 can correspond to the field-effect transistor 100 according to FIG. 1; in this respect, reference is made to the description there. Identical elements are also denoted by identical reference signs.

The difference from the field-effect transistor 100 is here in particular how the gate trenches 111 and webs 141, 142 and thus the p-doped second shielding regions 132 are formed. Here, the webs do not branch off the (actual) gate trench alternately laterally, but rather on the same side (here on the right) of the gate trench. A type of ring gate trench is formed together with a further gate trench (on the right side in FIG. 2) and the webs thereof, which branch off on the other side (here on the left). This structure can continue in the x- and y-directions so that the gate trench forms a type of grid with the webs.

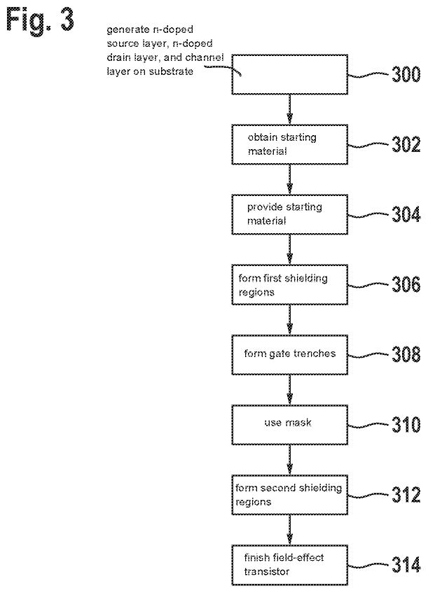

FIG. 3 schematically shows a sequence of a method according to the present invention in a preferred embodiment, viz., by way of example, for producing a field-effect transistor as shown, for example, in FIG. 1 or 2.

In a step 300, the n-doped source layer 104, the n-doped drain layer and the channel layer 106 located vertically therebetween can first be generated on a substrate 122 as a layer stack. The n-doped drain layer may comprise the optional layers mentioned with respect to FIG. 1. The starting material 302 thus obtained can then be provided in step 304.

In a step 306, the first shielding regions, e.g., p− or p+-doped first shielding regions, as, for example, denoted by 131 in FIG. 1, can then be formed, which extend vertically from the n+-doped source layer or the neighboring semiconductor surface to the n-doped drain layer and adjoin the channel layer. This can, for example, take place by means of implantation.

In a step 308, the gate trenches can then be formed by removing corresponding material, e.g., by etching. This can, for example, take place using a mask 310, which is, for example, applied to the starting material and represents the gate trenches. In this case, the gate trenches are designed in such a way that they comprise one or more webs which, in one or more delimited regions, extend horizontally at least to the p− or p+-doped first shielding region.

In a step 312, the p− or p+-doped second shielding regions, as, for example, denoted by 132 in FIG. 1, can then be formed vertically below a bottom of a relevant gate trench, for example by means of implantation. The p− or p+-doped second shielding regions thus extend to, in particular overlap with, the p− or p+-doped first shielding regions.

In a step 314, the field-effect transistor can then be finished by forming gate oxide, conductive gate electrode material and gate insulation (i.e., introducing the gate electrode) in the trenches or gate trenches, by optionally thinning back the substrate, and by contact formation and power metallization.

What is claimed is:

1. A semiconductor component, comprising:
a source layer doped according to a first type;
a drain layer doped according to the first type;
a channel layer located vertically between the source layer doped according to the first type and the drain layer doped according to the first type;
a gate trench, which extends vertically from the source layer doped according to the first type to the drain layer doped according to the first type and adjoins the channel layer and at least a portion of the source layer doped according to the first type;
a first shielding region doped according to a second type, which extends vertically from the source layer doped according to the first type, or a semiconductor surface adjoining it, to the drain layer doped according to the first type;
a second shielding region doped according to the second type, which is arranged vertically below a bottom of the gate trench, wherein the gate trench and the second shielding region doped according to the second type are configured such that, in one or more delimited regions, the second shielding region doped according to the second type extends horizontally at least to the first shielding region doped according to the second type.

2. The semiconductor component according to claim 1, wherein the semiconductor component is a transistor.

3. The semiconductor component according to claim 1, wherein the gate trench and the second shielding region doped according to the second type are strip-shaped, as seen in a horizontal direction, with one or more branching-off webs, which extend to the one or more delimited regions.

4. The semiconductor component according to claim 1, wherein the second shielding region doped according to the second type is formed in the gate trench by implantation.

5. The semiconductor component according to claim 1, wherein the drain layer doped according to the first type includes a drift layer doped according to the first type and a spread layer doped according to the first type, wherein the spread layer doped according to the first type is more highly doped than the drift layer doped according to the first type and adjoins the channel layer.

6. The semiconductor component according to claim 1, wherein the channel layer is doped according to the second type at least partially.

7. The semiconductor component according to claim 1, further comprising:
a gate electrode which has a conductive gate electrode material at least partially surrounded by a dielectric, and which is introduced into the gate trench.

8. The semiconductor component according to claim 1, wherein the semiconductor component is a SiC or GaN or gallium-oxide field-effect transistor.

9. A method for producing a semiconductor component, comprising the following steps:
providing a starting material including: a source layer doped according to a first type, a drain layer doped according to the first type, on a substrate doped according to the first type, and a channel layer located vertically between the source layer doped according to the first type and the drain layer doped according to the first type;
forming a first shielding region doped according to a second type, which extends vertically from the source layer doped according to the first type, or a semiconductor surface adjoining it, to the drain layer doped according to the first type;
forming a gate trench which extends vertically from the source layer doped according to the first type to the drain layer doped according to the first type and adjoins the channel layer and at least a portion of the source layer doped according to the first type; and
forming a second shielding region doped according to the second type, vertically below a bottom of the gate trench;
wherein the gate trench and the shielding region doped according to the second type are configured in such a way that, in one or more delimited regions, the second shielding region doped according to the second type extends horizontally at least to the first shielding region doped according to the second type.

10. The method according to claim 9, wherein the semiconductor component is a transistor.

11. The method according to claim 9, wherein the gate trench and the second shielding region doped according to the second type are strip-shaped, as seen in a horizontal direction, with one or more branching-off webs, wherein the webs extend to the one or more delimited regions.

12. The method according to claim 9, wherein the gate trench is formed first, and wherein the second shielding region doped according to the second type is formed after the gate trench is formed.

13. The method according to claim 12, wherein the second shielding region doped according to the second type is formed in the gate trench by implantation.
